(19) United States
(12) Patent Application Publication
(10) Pub. No.: US 2010/0118486 A1
(43) Pub. Date: May 13, 2010

(54) HEAT-DISSIPATION APPARATUS FOR COMPUTER HOST

(76) Inventor: Yen-Wen Su, Taoyuan City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 12/270,127

(22) Filed: Nov. 13, 2008

(51) Int. Cl. H05K 7/20

(52) U.S. Cl. 361/679.48

(57) ABSTRACT

A heat-dissipation apparatus for a computer host is provided, particularly a heat-dissipation apparatus disposed on the housing, wherein a fan module and a plurality of lighting components are included. In one embodiment, a flexible circuit board is interconnected therebetween, and disposed surrounded the framework of the fan module. Users may utilize a control switching module to control the fan module and the lighting components.

### BACKGROUND OF THE INVENTION

1. Field of the Invention

The present invention relates to a computer host heat-dissipation apparatus; in particular, to a control switching module for controlling the use of a fan module and lighting components of the heat-dissipation apparatus.

2. Description of Related Art

For a computer system, especially a desktop computer, it is common to use a housing to encapsulate internal components of the entire system. However, while the housing serves the features of aesthetics, anti-dust, and protection, it is inevitable to encounter the problem of heat generated by components therein; thus, heat-dissipation off the housing has become one important consideration in terms of system stability. For current computer system requirements, there usually are various heat-dissipation fans stalled in the housing, including fans applied in/on the power supply, central processing unit, or display card, furthermore other types of heat-dissipation devices can be also employed, such as heat-dissipation fans, heat-dissipation fins, different types of coolers (e.g. thermal electric cooler), or cooling condensers.

Also, in general, upon booting a computer system, a user may, through the setting screen of the Basic Input/Output System (BIOS), be aware of current system status, such as processor temperature, power supply temperature, and relevant fan rotation speed; or alternatively, it is also possible to acquire such related information by means of specific software after successfully loading the computer system. FIG. 1 shows a perspective view of a conventional general desktop computer, wherein the housing 10 encapsulates internal components of the computer system; outside the housing a plurality of holes is utilized for installing the heat-dissipation fan 18 to reduce the temperature inside the housing. Also, on the housing panel 12 there are always some light indicators 16 and switches 14 installed, wherein the light indicators 16 commonly is composed of Light Emitting Diode (LED's) that briefly indicates the operation status of the computer system, which may include a power source light indicator, a hard disc drive light indicator, or additionally operation light indicators for some other peripheral devices, e.g. CD/DVD drive, floppy disc drive, card reader, and so forth. The above-mentioned heat-dissipation fan installed onto the computer housing is usually a continuously operating fan, which is not connected to any temperature sensing device, nor provided with any mechanism for rotation speed control. Whereas, as shown in FIG. 2, a diagram of connections for internal components of the conventional computer system, the processor fan 202 does provide the feature of rotation speed adjustment through the temperature control mechanism of the system.

The internal components of the computer system shown in FIG. 2 are all the components installed on the computer motherboard 20, and in appearance, comprise at least the processor 203, system chip set 206, Basic Input/Output System 205, system memory 207, and system bus 208 connected to other peripheral devices. Also, in the present example and specifically regarding to the heat dissipation of the processor 203, it further comprises the temperature sensor 204, processor fan 202, and fan control circuit 201 thereof, and the like.

In prior art, to achieve the purpose of effective temperature reduction in the processor 203, installation of the processor fan 202 is required which allows a user to control operation conditions of the entire computer system via the monitoring by the Basic Input/Output System 205. It uses the temperature sensor 204 to sense the temperature in the processor 203 and feeds the measured temperature back to the Basic Input/Output System 205, causing the fan control circuit 201 of the Basic Input/Output System 205 to control the rotation speed of the processor fan 202, thus enabling temperature reduction in the processor 203. Through the interface provided by the computer system or other relevant software, the user can further appreciate the current operation status of the system via the Basic Input/Output System 205.

### SUMMARY OF THE INVENTION

In view that a conventional computer system provides very simple indications of system operation status only through the housing panel, and a general user needs some software interface to know the internal operation conditions, thus the present invention provides a computer host heat-dissipation apparatus which uses a control device installed onto the computer housing panel to control each heat-dissipation module and light indicator directly through the control switches on the panel.

The preferred embodiment of the present invention discloses a heat-dissipation apparatus installed on the outside of the computer host housing, which includes a control switching module, a fan module, and lighting components. In particular the control switching module is installed to allow a user to control the fan module and the lighting components, wherein the fan module, not only has the rotation speed control feature provided by itself, but can further reflect the temperature condition through the lighting effects thereof.

### BRIEF DESCRIPTION OF THE DRAWINGS

FIG. 1 shows a perspective view of a conventional desktop computer;

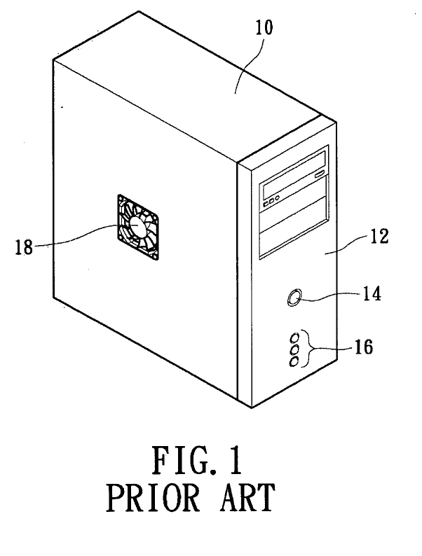

FIG. 2 shows a diagram of connections for internal components of the conventional computer system;

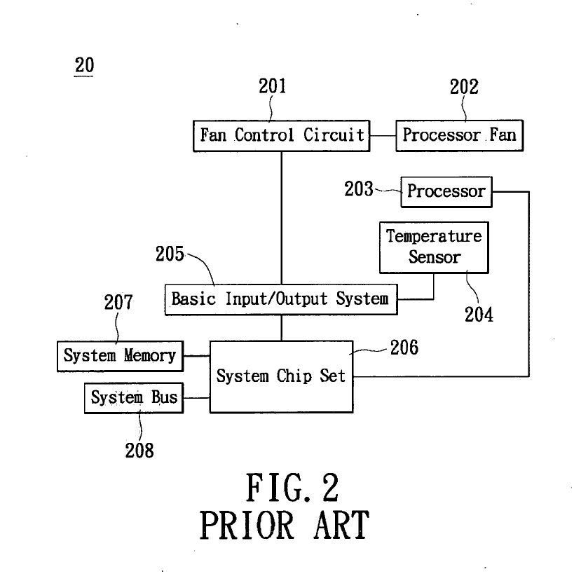

FIG. 3A shows a perspective view of a computer housing for a computer housing panel system having control and status indication features according to the present invention;

FIG. 3B shows a diagram of an embodiment for a control knob according to the present invention;

FIG. 4 shows a perspective view of a computer housing for another embodiment according to the present invention;

FIG. 5A shows a perspective view of a heat-dissipation fan having control feature according to the present invention; and

FIG. 5B shows a perspective view of a computer housing installed with the heat-dissipation fan according to the present invention.

### DETAILED DESCRIPTION OF PREFERRED EMBODIMENTS

In prior art, there are some light indicators installed on the computer housing panel, the light indicators mostly displaying certain basic status of the computer in a passive way. Regarding this issue, the present invention provides an improved apparatus allowing a user to control one or more heat-dissipations devices inside the computer housing through the control interface installed on the computer housing, in which such heat-dissipations devices are essentially classified into two types, one being independent modules from the computer system, such as independently operating heat-dissipation fans, having independent circuit without need to be connected to the computer system (but allowed to use the power supplied by the computer host), which can use a temperature sensor to measure the internal temperature inside the housing to show current status with independent light indicators, so as to control the independently operating heat-dissipation fan by means of independent control switches.

The other type is connected to the original computer host, which, other than the power acquired from the computer host power supply, is further jointed with the circuits in the computer to employ resources from the original computer system, such as determination of current operating temperature in the processor through the temperature sensor of the original processor, and controls the rotation speed of the heat-dissipation fan via the control circuit thereof (i.e. the fan control circuit); or alternatively, it reflects the temperature in such a processor by using the light indicators installed on the housing panel; additionally, the control range may be further extended to other heat-dissipation modules in the power supply, display card, and the housing itself.

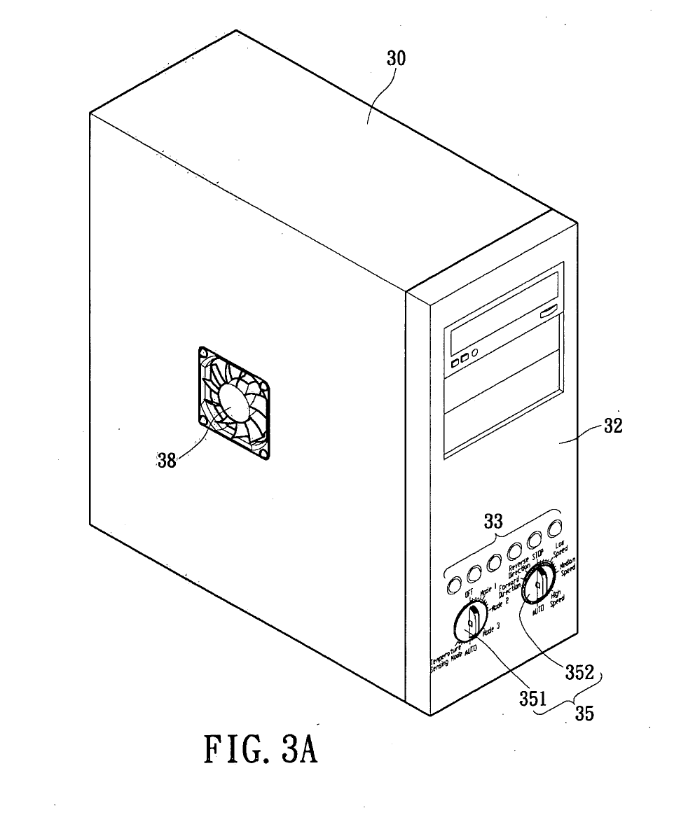

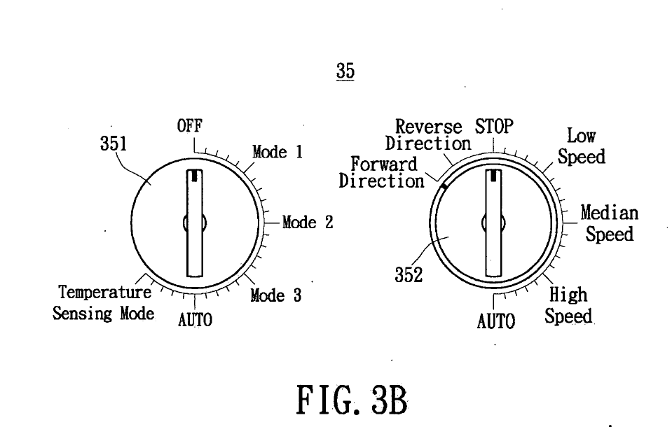

Refer now to FIG. 3A, wherein a perspective view of a computer housing for a computer housing panel system having control and status indication features according to the present invention is shown. As an embodiment of the present invention, in the present Figure, it shows a perspective view of a computer housing 30, and on the panel 32 there install multiple signal lights 33 with control interface; the rotation knobs 35 of the embodiment shown in the Figure may respectively control the lighting mode and fan rotation in a fashion of rotation, and additionally on the side board there installs a heat-dissipation fan 38 for heat-dissipation inside the housing. Especially, it is noted that the aforementioned signal lights 33, control knobs 35, and heat-dissipation fan 38 together form a basic component of the panel system having control and status display features, whose control circuit is not shown in the present Figure.

Therein, in the basic composition of the panel system in the computer host heat-dissipation apparatus, the multiple signal lights 33 can, in addition to indication of operation conditions in power source, hard disc drive, or other peripheral devices, further show the temperature condition of each portion inside the computer system, while the control knobs 35 provide the interface for controlling rotation speed of each heat-dissipation fan. For example, the user can appreciate the temperature inside the computer housing by way of colors or other indications in the signal lights 33 and use the control knob 35 to increase or decrease the rotation speed of the heat-dissipation fan 38 in order to draw away the hot air inside the housing.

The embodiments of the above-mentioned control knob 35 can be the individual light control interface 351 and fan control interface 352 as shown in FIG. 3B, in which the preferred embodiment can be accomplished in a fashion of rotation of a knob. Herein the light control interface 351 allows the user to conveniently control various lighting modes by means of a knob, shown in the Figure as several selective scales, including OFF, Mode 1, Mode 2, Mode 3, AUTO and Temperature Sensing mode. The Mode 1, Mode 2, and Mode 3 can be multiple lighting modes allowable for the user to select, such as lights being presented in a way of blinking, multi-color switching, marquee etc.; or adjusted to AUTO, allowing to present according to default factory settings; or else adjusted to Temperature Sensing mode, allowing the result of temperature sensing to be presented by means of lighting effects.

Furthermore, the fan control interface 352, as shown in the embodiment of FIG. 3B, Which operates in via a knob, and thereby a user can control the rotation mode of the fan, including modes such as STOP, Low Speed, Median Speed, High Speed, etc., wherein it is possible to fine tune to other rotation speeds, rather than being limited to the above-said three speed options; or allowed to select AUTO to enable appropriate speed based on the result of temperature sensing; or otherwise providing additional options of forward direction and reverse directions to allow the fan control interface 352 to present more rotation effects.

Except the two knobs as shown in the Figure, it is also possible for the multi-functional light control interface 351 and fan control interface 352 to be integrated in a single knob, with another switch to select the control item, or otherwise implemented by using multiple control buttons; that is, it is by no means limited to the present embodiment depict in the Figure.

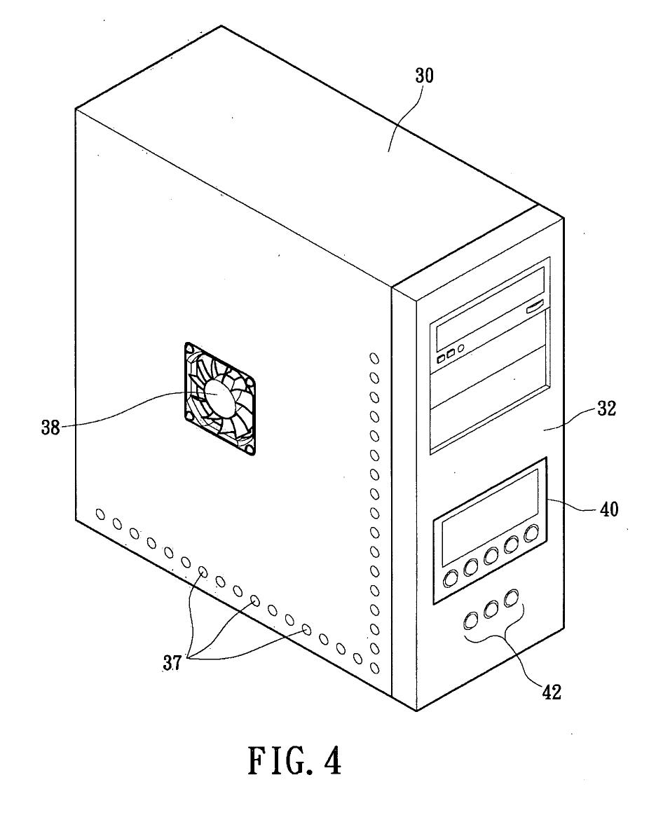

FIG. 4 shows a perspective view of a computer housing for another embodiment according to the present invention. The present Figure also illustrates an embodiment of the computer housing 30; there on the side board of the housing install a heat-dissipation fan 38 and a plurality of lighting components 37, and on the housing panel 32 there is a display and control panel 40 for showing a message, and a plurality of signal lights 42. The lighting components 37 and signal lights 42 may be lights simply for decorative purpose, or may be light indicators used to reflect the temperature conditions, while the signal lights 42 may display operation conditions in system power source, hard disc driver or other peripheral devices. The display and control panel 40 consists of a display screen and a control interface.

In the present example, the display and control panel 40 displays the temperature value measured by each internal temperature sensor through the display screen, or presents the temperature value by scales. In the present example, it is possible to connect to each temperature sensor on the motherboard circuit, such as the temperature sensor of the processor, via the BIOS in the original computer system, thereby acquiring the temperature in the processor. Besides, in addition to the temperature sensing mechanism provided by the original computer system, it is also possible to further add temperature sensors on other portions of the system, including display card, power supply, or the temperature sensor inside the housing. Such additional circuits can be electrically connected to the display and control panel 40, and the heat-dissipation module for each corresponding portion can be controlled through the display and control panel 40; that is, the user can operate through the control interface provided by the display and control panel 40, including adjusting displayed status, adjusting rotation speed in each fan, or even lighting effect of each lighting component 37.

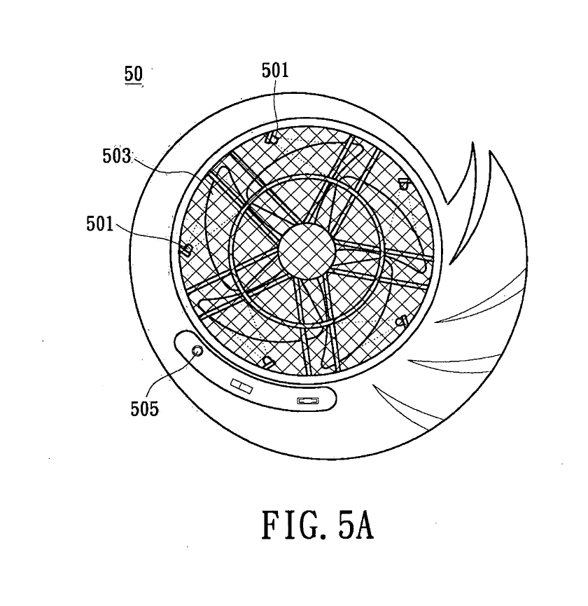

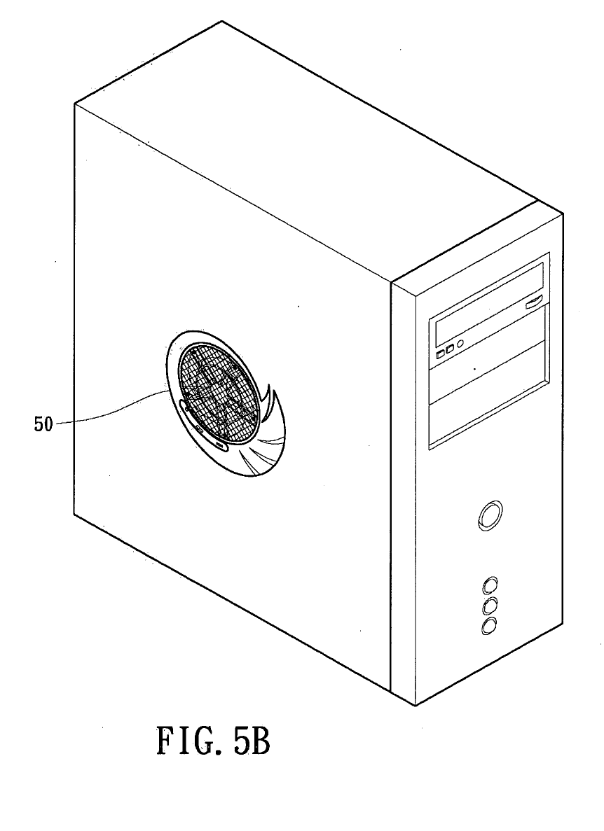

The panel system of the computer host heat-dissipation apparatus according to the present invention provides the control and status display feature, essentially by using the devices on the housing panel to show the temperature control message of the computer system, thus allowing, except independently operating devices, to further connect to the computer system and apply the existing temperature control mechanism configured in the original computer system. Therein the embodiment of the computer host heat-dissipation apparatus may be referred to FIGS. 5A and 5B.

FIG. 5A shows a perspective view of a computer host heat-dissipation apparatus 50 having control feature according to the present invention, which illustrates an independent heat-dissipation apparatus installed on the housing of the computer host, having a structure in appearance formed by a fan module 503 consisting of a plurality of blades, a plurality of lighting components 501, and the composition thereof. In the present embodiment, the plurality of light components 501 are mutually connected with a flexible circuit board, installed in a surrounded way on a peripheral framework of the fan module 503. In particular, on one side of the fan module 503, there installs a control switching module 505 allowable for operations by the user, thereby controlling the switching and rotation speed of the fan module 503, and further including controlling the use of the lighting components installed in a surrounded way on the periphery of the fan.

Particularly, the above-mentioned plurality of lighting components 501 are evenly installed on the peripheral framework of the fan module 503, specifically forming a circular structure to emit light onto the fan blades of the fan module 503, thus in combination with rotating fan blades creating special light effects. Furthermore, one embodiment of such a computer host heat-dissipation apparatus 50 operates independently from the computer system, in which the computer system simply provides power thereto, and the control switching module 505 of the computer host heat-dissipation apparatus 50 includes one or more switches installed on the peripheral framework of the fan module 503.

In another embodiment, the computer host heat-dissipation apparatus 50 is electrically connected to the BIOS of the computer system in a similar way, allowing to change the lighting status thereof based on the result of temperature sensing from the BIOS, including color changing, blinking etc., while the fan module 503 modifies the rotation speed thereof in accordance with result of temperature sensing from the BIOS.

FIG. 5B shows a perspective view of the computer host heat-dissipation apparatus 50 installed onto the computer housing 5 of the present invention, in which the position of placement and number of heat-dissipation apparatus are based on actual needs.

In summary, the present invention relates to a computer host heat-dissipation apparatus, installed onto the computer housing, thereby controlling the fan and lighting components on the computer housing to facilitate more efficient and real-time operations. However, the descriptions illustrated heretofore simply set forth preferred embodiments of the present invention, rather than limiting the scope of the present invention thereto; all effectively equivalent modifications, alternations, and changes made with reference to the disclosure of the present invention and appended drawings are reasonably deemed to be encompassed by the scope of the present invention as define by the following claims.

What is claimed is:

1. A computer host heat-dissipation apparatus which is an independent heat-dissipation apparatus installed onto a housing of a computer host, comprising:
a fan module;
a plurality of lighting components, mutually connected by means of a flexible circuit board, installed on the peripheral framework of the fan module; and
a control switching module, used to control the fan module and plurality of lighting components.

2. The computer host heat-dissipation apparatus according to claim 1, wherein the plurality of lighting components are evenly installed on the peripheral framework of the fan module, thereby forming a circular structure.

3. The computer host heat-dissipation apparatus according to claim 1, wherein the control switching component consists of one or more switches installed on the peripheral framework of the fan module.

4. The computer host heat-dissipation apparatus according to claim 1, wherein computer host heat-dissipation apparatus is electrically connected to a power source of the computer host.

5. The computer host heat-dissipation apparatus according to claim 1, wherein computer host heat-dissipation apparatus is electrically connected to the Basic Input/Output System (BIOS) of a computer system.

6. The computer host heat-dissipation apparatus according to claim 5, wherein the lighting components of the computer host heat-dissipation apparatus change the lighting status thereof based on the result of temperature sensing from the Basic Input/Output System.

7. The computer host heat-dissipation apparatus according to claim 6, wherein the lighting status of lighting components of the computer host heat-dissipation apparatus includes color changing or blinking effects.

8. The computer host heat-dissipation apparatus according to claim 5, wherein the fan module of the computer host heat-dissipation apparatus changes the rotation speed thereof based on the result of temperature sensing from the Basic Input/Output System.
